(19) United States
(12) Patent Application Publication
(10) Pub. No.: US 2014/0224329 A1
(43) Pub. Date: Aug. 14, 2014

(54) DEVICES INCLUDING ORGANIC MATERIALS SUCH AS SINGLET FISSION MATERIALS

(71) Applicant: Massachusetts Institute of Technology, Cambridge, MA (US)

(72) Inventors: Daniel N. Congreve, Cambridge, MA (US); Marc A. Baldo, Lexington, MA (US); Nicholas John Thompson, Quincy, MA (US)

(73) Assignee: Massachusetts Institute of Technology, Cambridge, MA (US)

(21) Appl. No.: 14/096,657

(22) Filed: Dec. 4, 2013

Related U.S. Application Data
(60) Provisional application No. 61/732,988, filed on Dec. 4, 2012.

(51) Int. Cl. H01L 51/42; H01L 51/00

(52) U.S. Cl. CPC H01L 51/42; H01L 51/0054; H01L 51/0055
USPC 136/263

(57) ABSTRACT

Embodiments described herein relate to devices containing photoactive materials that, in some cases, undergo singlet fission. In some cases, the devices (e.g., solar cells) can efficiently convert photonic energy into usable electricity, with external quantum efficiencies greater than 100% in the visible region.

### RELATED APPLICATIONS

This application claims priority under 35 U.S.C. §119(e) to co-pending U.S. Provisional Application Ser. No. 61/732,988, filed Dec. 4, 2012, the contents of which are incorporated herein by reference in its entirety for all purposes.

### FIELD

Embodiments described herein in relate to devices containing photoactive materials, including singlet fission materials.

### BACKGROUND

Conventional solar cells generate one electron for each photon that is absorbed. The output voltage is typically defined by the bandgap, and solar cells often waste any excess photon energy as heat. Summing the thermal loss over the solar spectrum yields the Shockley-Queisser efficiency limit of 34% for solar cells containing a single, optimized semiconductor junction.

### SUMMARY

Various devices including photoactive materials are provided. In some embodiments, the device comprises a donor material comprising an optionally substituted polyacene species or an optionally substituted polyene species; an acceptor material having a first side in physical contact with the donor material, and a second, opposing side; and at least one electrical contact in physical contact with the second, opposing side of the acceptor material, wherein the donor material is not in physical contact with an electrical contact.

In some embodiments, the device comprises a donor material comprising an organic compound having a singlet energy and a triplet energy, wherein the singlet energy is about two times greater than the triplet energy; an acceptor material having a first side in physical contact with the donor material, and a second, opposing side; and at least one electrical contact in physical contact with the second, opposing side of the acceptor material, wherein the donor material is not in physical contact with an electrical contact.

In some embodiments, the device comprises a donor material comprising an organic compound; an acceptor material having a first side in physical contact with the donor material, and a second, opposing side; and at least one electrical contact in physical contact with the second, opposing side of the acceptor material, wherein the organic compound is not pentacene.

In some embodiments, the device comprises a singlet fission material comprising an organic compound having a singlet energy and a triplet energy, wherein the singlet energy is about two times greater than the triplet energy; a triplet emitter species in electronic or excitonic communication with the singlet fission material; and a silicon material in optical or excitonic communication with the triplet emitter species. In some embodiments, the organic compound may have a singlet energy of greater than about 2.2 eV and/or a triplet energy of greater than about 1.1 eV. The device may further comprise at least one electrical contact in physical contact with the silicon material and, optionally, with the singlet fission material.

In some embodiments, the device comprises a singlet fission material; an organic electron acceptor material (e.g., a fullerene such as C₆₀) or an organic electron donor material in contact with the singlet fission material; and an inorganic material in physical contact with the singlet fission material. In some embodiments, the singlet fission material may be an electron donor material and the inorganic material may be an electron acceptor material.

Methods for producing a photocurrent are also provided comprising exposing a device comprising a singlet fission material comprising an organic compound in electronic or excitonic communication with a triplet emitter species, and an acceptor material in optical or excitonic communication with the triplet emitter, to a source of energy to produce an excitation energy within the singlet fission material; and allowing the excitation energy to transfer from the singlet fission material to the acceptor material (e.g., via the triplet emitter species) such that the device produces a photocurrent.

In any of the foregoing embodiments, the donor material may be an exciton donor material and the acceptor material may be an exciton acceptor material. In any of the foregoing embodiments, the donor material may be an electron donor material and the acceptor material may be an electron acceptor material.

In any of the foregoing embodiments, the optionally substituted polyacene species may be an optionally substituted tetracene or an optionally substituted pentacene. In some cases, the optionally substituted polyacene species is tetracene, rubrene, dithienyl tetracene, TIPS-tetracene, dibithienyl tetracene, diphenyl tetracene, terbutyl rubrene, pentacene, TIPS-pentacene, diphenyl pentacene, dibiphenyl pentacene, dithienyl pentacene, or dibithienyl pentacene. In some cases, the optionally substituted polyene species is diphenylbutadiene, diphenylhexatriene, or diphenyloctatetraene. In some cases, the optionally substituted polyacene comprises a heteroatom. In one embodiment, the optionally substituted polyacene is diphenyl isobenzofuran.

In any of the foregoing embodiments, the acceptor material may comprise an inorganic material. In some embodiments, the acceptor material comprises an inorganic material such that the donor material and the acceptor material form an organic-inorganic heterojunction. In some embodiments, the acceptor material comprises silicon.

In any of the foregoing embodiments, the acceptor material may comprise an organic material such as fullerenes, nanotubes, and/or nanorods, any of which are optionally substituted. In some embodiments, the acceptor material may be an optionally substituted fullerene. In some embodiments, the acceptor material may be C₆₀.

In any of the foregoing embodiments, the device may further comprise an exciton blocking layer. In some embodiments, the exciton blocking layer may comprise a conducting polymer. In some embodiments, the conducting polymer may comprise polyaniline, polythiophene, polypyrrole, polyphenylene, polyarylene, poly(bisthiophene phenylene), a ladder polymer, poly(arylene vinylene), poly(arylene ethynylene), metal derivatives thereof, or substituted derivatives thereof. In some embodiments, the conducting polymer may be polythiophene or a substituted derivative thereof. In some embodiments, the exciton blocking layer may comprise poly(3-hexylthiophene).

In any of the foregoing embodiments, the device may further comprise a triplet emitter species in electronic or excitonic communication with the donor material. In some embodiments, the triplet emitter species may be phosphorescent in the range of about 700 nm to about 1100 nm. In some embodiments, the triplet emitter species may comprise a metal species. In some embodiments, the triplet emitter species may be a quantum dot or an optionally substituted porphine. In some embodiments, the triplet emitter species may comprise Pt(II) meso-tetraphenyl tetrabenzoporphine, Pt(II) tetraphenyl benzoporphine, Pt(II) octaethyl porphine, Pd(II) tetrabenzoporphine, Pt(II) meso-tetra(pentaflurophenyl) porphine, Pt(II) tetrabenzoporphine, Pd(II) meso-tetraphenyl porphine, Pt(II) aza-triphenyltetrabenzoporphyrin, Pt(II) tetraphenyltetranaphtho[2,3]porphyrin, PbS quantum dots, PbSe quantum dots, CdS quantum dots, CdSe quantum dots, or InAs quantum dots.

Systems comprising at least two devices as in any of the foregoing embodiments are also provided, wherein the at least two devices are arranged in tandem.

### BRIEF DESCRIPTION OF THE DRAWINGS

FIG. 1 shows (a) examples of organic donor materials and (b) a schematic of singlet exciton fission in pentacene based on calculations of the singlet and triplet excitons and charge transfer states at the pentacene/fullerene interface, with delocalized singlet excitons and two localized triplet excitons indicated by dotted circles.

FIG. 2 shows (a) a back-contacted device containing a singlet fission material and an inorganic material; (b) a device containing a singlet fission material and an inorganic material, with contacts at the front and back of the device; (c) a system of parallel devices containing a singlet fission material and an inorganic material; (d) a device containing a singlet fission material, an inorganic material, and a mixed layer containing both a singlet fission material and a triplet emitter species positioned between the singlet fission material and the inorganic material; and (e) a device containing a singlet fission material, an inorganic material, and a layer containing a triplet emitter species positioned between the singlet fission material, and the inorganic material.

FIG. 3 shows a device containing an organic-inorganic heterojunction and an exciton blocking layer.

FIG. 4 shows (a) a device containing a singlet fission material, an inorganic material, and a mixed layer containing the singlet fission material and an electron acceptor material; and (b) a device containing a singlet fission material, an inorganic material, and a mixed layer containing the singlet fission material and an electron donor material.

FIG. 5 shows (a) the architecture of the solar cell, as well chemical structures of its components, according to one embodiment; and (b) a plot of external quantum efficiencies of the device in (a), including (i) the external quantum efficiency of the device measured with light incident at 10° from normal with an external mirror reflecting the residual pump light; (ii) the external quantum efficiency of the device without optical trapping, and optical fits from IQE modeling for comparison to the measured device efficiency without optical trapping for (iii) modeled device EQE; (iv) modeled P3HT EQE; and (v) modeled pentacene EQE.

FIG. 6 shows a plot of current density-voltage characteristics for the pentacene solar cell measured under dark (dashed line) or AM1.5G 100 mW/cm² (solid line) conditions without optical trapping.

FIG. 7 shows (a) a plot of the magnetic field dependent change in photocurrent measured at B=0.4 T as a function of pentacene layer thickness; (b) a plot of triplet yield from singlet exciton fission; and (c) a plot comparing the maximum achievable quantum yield determined from the magnetic field effect (solid line) with the internal quantum efficient as determined from EQE measurements and the calculated optical absorption for devices including a photodetector containing a pentacene layer sandwiched between C₆₀ acceptor films (squares), a photodetector containing a pentacene layer sandwiched between PTCBI acceptor films (squares), and the solar cell architecture of FIG. 5A (circles).

Other aspects, embodiments and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### DETAILED DESCRIPTION

Embodiments described herein relate to devices containing photoactive materials (e.g., singlet fission materials). In some cases, the devices (e.g., solar cells) can efficiently convert photonic energy into usable electricity, with external quantum efficiencies greater than 100% in the visible region.

An advantageous feature of some embodiments described herein is the incorporation of singlet fission materials to produce devices having enhanced solar conversion efficiency. Use of singlet fission materials within, for example, photovoltaic devices such as solar cells can allow for a potential doubling of photocurrent. The terms singlet fission and single exciton fission are known in the art and refer to a type of multiple exciton generation mechanism found in some materials, such as organic semiconductors, whereby high energy photons (e.g., 2<550 nm) are absorbed by a material to produce a singlet exciton, which is then converted into two triplet excitons. Incorporation of materials which undergo singlet fission may provide the ability to achieve solar conversion efficiencies that exceed the single p-n junction efficiency limit Additionally, competing processes in which energy is lost may be reduced or prevented, since spin conservation disallows thermal relaxation of the high-energy excitons into a single low-energy exciton.

Some embodiments provide devices comprising a photoactive material, and electrode material(s) in contact with the photoactive material. In some cases, the device is a photovoltaic cell, such as a solar cell. Photovoltaic cells generally include at least a photoactive material and at least two electrodes (e.g., an anode and a cathode). The device may also comprise a substrate (e.g., on which to form the anode and/or cathode), electron-blocking and/or electron-transporting materials, exciton-blocking and/or exciton-transporting materials, circuitry, a power source, and/or an electromagnetic radiation source. In some cases, the photoactive material may be positioned between two electrodes. The photoactive material may include components having a donor-acceptor interaction, such as an exciton donor material and an exciton acceptor material, or, an electron donor material and an electron acceptor material. The components of the photoactive material may be selected and arranged to establish sufficient donor-acceptor interfacial area to favor exciton transfer/dissociation and efficient transport of separated charges to the respective electrodes. In some cases, the photoactive material may absorb photonic energy (e.g., electromagnetic energy), which can be converted into electrical energy. In some embodiments, the conversion may take place via an electrical mechanism. In some embodiments, the conversion may take place via another mechanism, such as an optical mechanism.

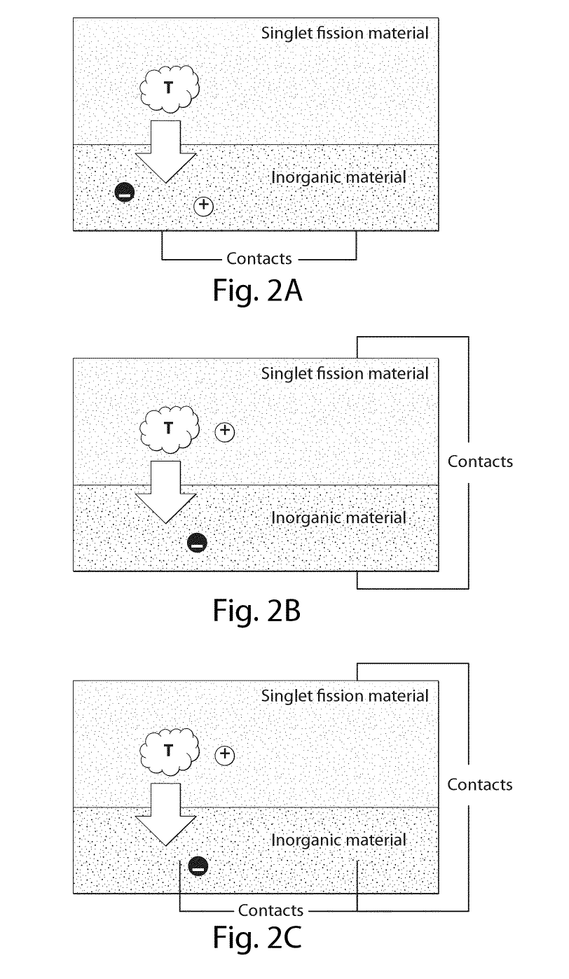

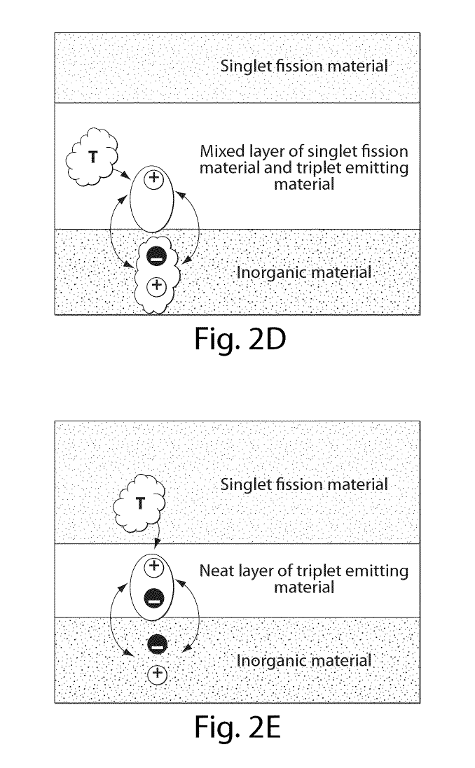

In some embodiments, the device includes a photoactive material capable of undergoing singlet fission. Such photoactive materials may include a donor material and an acceptor material selected and arranged such that, in operation, the donor material absorbs photonic energy (e.g., light) to produce singlet excitons, which then undergo singlet fission to produce two triplet excitons per singlet exciton. In some embodiments, energy may be extracted directly from the triplet excitons by allowing the triplet excitons to dissociate into charge. Such a process may occur, for example, at a junction between an exciton donor material (e.g., pentacene) and an exciton acceptor material (e.g., silicon). For example, low energy photons may pass through an exciton donor material (e.g., a singlet fission layer) and may be converted to electricity directly by the exciton acceptor material. In some cases, the photoactive material may include an electron donor material and an electron acceptor material (e.g., a fullerene such as C₆₀), arranged such that an exciton may dissociate into separate charges (i.e., holes and electrons) at the interface between the electron donor material and electron acceptor material. The separated holes and electrons may then be collected to produce a current. FIGS. 2B-2C show examples of devices which include an organic-inorganic heterojunction between an organic material (e.g., a singlet fission material) and an inorganic material, where excitons may dissociate at the organic-inorganic interface to generate current.

In another set of embodiments, energy transfer from the donor material to the acceptor material may occur optically, for example, via energy transfer (e.g., fluorescence resonance energy transfer or FRET, or surface resonance energy transfer or SRET). For example, the device may include an exciton donor material, an exciton acceptor material, and a triplet emitter species selected and arranged such that, in operation, the exciton donor material may absorb photonic energy (e.g., light) to produce singlet excitons, which then undergo singlet fission to produce two triplet excitons per singlet exciton. Typically, triplet excitons alone may not produce an emission; however, in the presence of a triplet emitter species, the triplet excitons may interact with the triplet emitter species to produce an emission (e.g., phosphorescence), which may be absorbed by or transferred to the exciton acceptor material.

In some embodiments, a triplet exciton may be transferred intact from a first component of the device to a second component of the device, followed by dissociation of the triplet into separate charges within the second component. For example, the photoactive material may include an exciton donor material and an exciton acceptor material, arranged such that a triplet exciton may first be transferred from the exciton donor material to the exciton acceptor material intact, and may then dissociate into separate charges within the exciton acceptor material. FIG. 2A shows one embodiment of a device that includes a singlet fission layer (e.g., exciton donor material) arranged directly on top of an inorganic material (e.g., exciton acceptor material), which allows for direct transfer of a triplet exciton from the exciton donor material to the exciton acceptor material. The transfer may occur, for example, via a wavefunction overlap or Dexter-type transfer. The triplet exciton may then dissociate into charges to generate current.

FIG. 2D shows another illustrative embodiment where a device includes a singlet fission material (e.g., as an exciton donor material), an inorganic material (e.g., as an exciton acceptor material), and an intermediate layer arranged between and in contact with the singlet fission material and the inorganic material, The intermediate layer (e.g., a “mixed” layer) may include a mixture of singlet fission material and a triplet emitter species. In operation, triplet excitons generated in the singlet fission material may diffuse to the intermediate layer, and the triplet exciton may be transferred intact to the triplet emitter species. Subsequent transfer of the exciton from the triplet emitter species into the underlying inorganic material may occur via a wavefunction overlap method, or, in some cases, resonant energy transfer (e.g., FRET or SRET). FIG. 2E shows another illustrative embodiment, where the device includes a singlet fission material, an inorganic material, and a layer containing the triplet emitter species arranged between and in contact with the singlet fission material and the inorganic material. In operation, triplet excitons generated in the singlet fission material may diffuse to the layer of triplet emitter species, and the triplet excitons may be transferred intact to the triplet emitter species. Subsequent transfer of the exciton from the triplet emitter species into the underlying inorganic material may occur in a similar manner as in FIG. 2D. The devices in FIGS. 2D-2E may optionally be back-contacted devices, as described more fully herein.

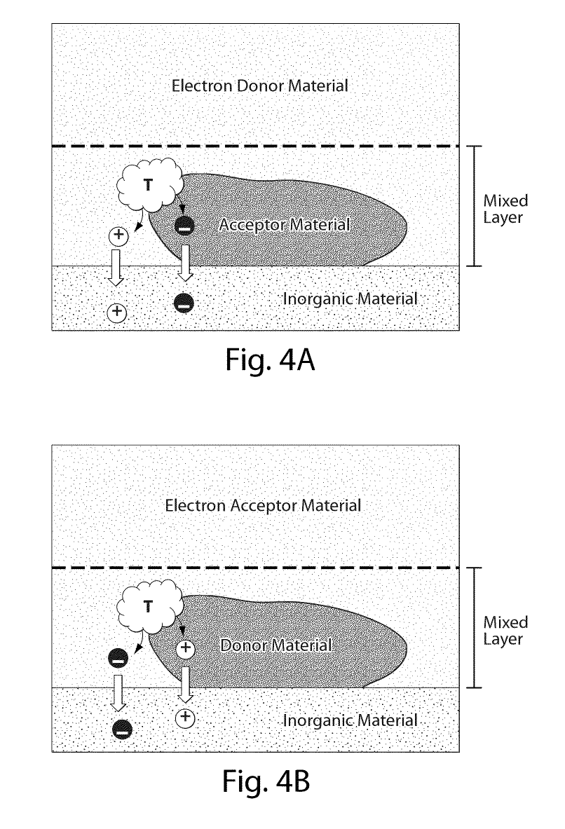

Other embodiments may involve dissociation of the triplet within one component of the device, followed by charge transfer to another component. For example, the device may include singlet fission material as an electron donor material, an inorganic material as an electron acceptor material, and an additional organic material that functions as an electron acceptor material or an electron donor material. FIG. 4A shows an illustrative embodiment of a device containing a singlet fission material, an inorganic material, and an intermediate “mixed” layer arranged between the singlet fission material and the inorganic material. The intermediate layer may include a singlet fission material and an additional electron acceptor material that is different from the inorganic material. In one embodiment, the singlet fission material may be pentacene, or another optionally substituted polyacene, and the additional electron acceptor material may be a fullerene such as C₆₀. In operation, triplet excitons generated in the single fission material may dissociate into separate charges at the interface between the single fission material and the additional electron acceptor material, i.e., within the intermediate layer. This may result in the generation of holes in the single fission material and electrons in the additional electron acceptor material, and both the holes and electrons may be independently transferred into the inorganic material.

Similarly, FIG. 4B illustrates a of a device containing a singlet fission material, an inorganic material, and an intermediate “mixed” layer arranged between the singlet fission material and the inorganic material that includes a singlet fission material and an additional electron donor material that is different from the singlet fission material. In operation, triplet excitons generated in the single fission material may dissociate into separate charges at the interface between the single fission material and the additional electron donor material, i.e., within the intermediate layer. This may result in the generation of electrons in the single fission material and holes in the additional electron donor material, and both the holes and electrons may be independently transferred into the inorganic material.

The devices may include one or more electrical contacts positioned at various locations in order to suit a particular application. In some cases, the device includes a donor material, an acceptor material in physical contact with, or at least in excitonic and optical or electronic communication with (e.g., via a triplet emitter species), the donor material, and at least one electrical contact (e.g., electrode) in physical contact with, or at least in electrical communication with, the donor material and/or acceptor material. Typically, the device includes two electrical contacts, or more. For example, the device may include two electrical contacts, where one electrical contact is in physical contact with the donor material and the other electrical contact is in physical contact with the acceptor material. FIG. 2B shows an illustrative embodiment where a device includes a singlet fission material, an inorganic material in contact with the singlet fission material, one electrical contact contacting the singlet fission material, and another electrical contact contacting the inorganic material.

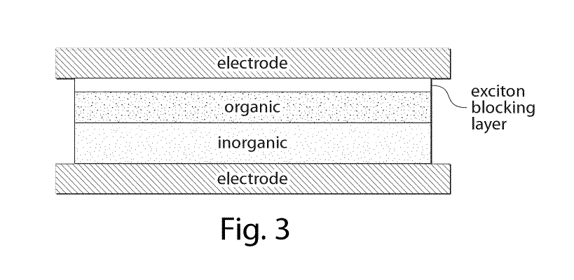

In another example, the device may include an additional component (e.g., an exciton blocking layer) physically separating an electrical contact from the donor and/or acceptor material. For example, the device may include two electrical contacts, where one electrical contact directly contacts the acceptor material but the other electrical contact is not in direct physical contact with the donor material. For example, the device may include an exciton blocking layer arranged between the one electrical contact and the donor material, as shown in FIG. 3.

In another example, the device may include two electrical contacts that are both in physical contact with the acceptor material, but are not in physical contact with the donor material (e.g., a back-contacted device). The device may also include additional components that may enhance device performance, such as triplet emitter species, as described more fully below. FIG. 2A shows an example of a back-contacted device, where both electrical contacts are in direct physical contact with the inorganic material but do not directly contact the singlet fission material. Such an arrangement may allow for collection of substantially all current from the inorganic portion of the device.

In some embodiments, the donor material and the acceptor material are both composed of inorganic materials. In some embodiments, the donor material and the acceptor material are both composed of organic materials. In some embodiments, the device may include an organic-inorganic heterojunction. For example, the donor material may contain an organic species and the acceptor material may include an inorganic species. In another example, the donor material may contain an inorganic species and the acceptor material may include an organic species. FIG. 2B illustrates a device containing an exciton donor material that may include an organic compound (e.g., a singlet fission material such as pentacene) and an acceptor material that includes an inorganic material (e.g., silicon). Electrodes may be arranged in contact with the donor material and the acceptor material. FIG. 3 shows another illustrative embodiment where an exciton blocking layer is arranged in between an organic donor material and an electrode. In some cases, devices including an organic-inorganic heterojunction may advantageously increase voltage and/or acceptor absorption, creating a highly efficient cell with minimal fabrication complexity.

FIGS. 2B-2C show examples of devices which include an organic-inorganic heterojunction between an organic material (e.g., a singlet fission material) and an inorganic material, where excitons may dissociate at the organic-inorganic interface to generate current. In FIG. 2B, electrical contacts are positioned in contact with the organic singlet fission material and the inorganic material such that holes may be collected via the organic singlet fission material and electrons may be collected through the inorganic material. In FIG. 2C, the device (e.g., tandem device) includes three electrical contacts arranged such that holes may be collected through the organic material (e.g., singlet fission material) while electrons may be collected through the n terminal of the inorganic material, or in some cases through both the n and p terminals of the inorganic material (e.g., silicon).

The ratio of total donor material to total acceptor material may be varied to suit a particular application. In some cases, the device includes a greater amount of total donor material relative to total acceptor material, by weight. In some cases, the device includes a greater amount of total acceptor material relative to total donor material, by weight. In some cases, the device includes essentially equal amounts of total donor material relative to total acceptor material, by weight.

The donor material may include any species capable of absorbing photonic energy and forming an excited state, such as a singlet excited state. In some cases, the donor material is an exciton donor material. In some cases, the donor material is an electron donor material. In some cases, the donor material includes an organic species, including organic compounds and polymers. In some cases, the donor material includes an organometallic species or an organic species associated with a metal (e.g., forming a complex). In some cases, the donor material is capable of functioning as a singlet fission material. Those of ordinary skill in the art would be capable of selecting appropriate donor materials that exhibit singlet fission properties. For example, the donor material may be selected to have a sufficiently high singlet energy and/or triplet energy, or a particular ratio of singlet energy to triplet energy such that singlet fission may occur. In some cases, the donor material may include an organic compound selected to have a singlet energy that is about two times greater than its triplet energy. In some cases, the organic compound may have a singlet energy of greater than about 2.2 eV and/or a triplet energy of greater than about 1.1 eV. In some cases, the organic compound may have a singlet energy of about 2.2 eV and a triplet energy of about 1.1 eV.

Some examples of singlet fission materials include polyacenes (e.g., pentacene), oligophenyls, tetracyano-p-quinodimethane, 1,3-diphenylisobenzofuran, perylene, tris-(8-hydroxyquinoline)aluminum, benzophenone, rubrene, carotenoids, conjugated polymers (e.g., polydiacetylenes, poly(diethyl dipropargylmalonate), poly(p-phenylene)s, poly(p-phenylene vinylene)s, poly(arylene)s such as polythiophene, etc.), polyacenes, o-quinodimethanes, and the like. Examples of other singlet fission materials are described in Smith, et al., “Singlet Fission,” Chem. Rev. 2010, 110(11), 6891-6936.

In one set of embodiments, the donor material is an optionally substituted polyacene species or an optionally substituted polyene species. The optionally substituted polyacene species may be a polycyclic aromatic hydrocarbon that includes a network of fused benzene rings having the following formula,

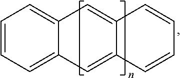

where n is 0, 1, 2, 3, 4, 5, 6, 7, 8, 9, 10, or greater than 10. In some cases, the polyacene species may be substituted with one or more additional functional groups. In some embodiments, the optionally substituted polyacene species may be an optionally substituted oligoacene species. In some embodiments, the optionally substituted polyacene species may be an optionally substituted naphthalene, an optionally substituted anthracene, an optionally substituted tetracene, an optionally substituted pentacene, or an optionally substituted hexacene. It should be understood that an optionally substituted polyacene containing any number of fused benzene rings may be suitable for use in embodiments described herein. Those of ordinary skill in the art would be able to select a polyacene species containing a desired number of fused benzene rings and/or the appropriate number and types of functional groups on the polyacene species in order to suit a particular application. In some cases, the optionally substituted polyacene species is an optionally substituted tetracene or an optionally substituted pentacene. Examples of such species include tetracene, rubrene, dithienyl tetracene, TIPS-tetracene, dibithienyl tetracene, diphenyl tetracene, terbutyl rubrene, pentacene, TIPS-pentacene, diphenyl pentacene, dibiphenyl pentacene, dithienyl pentacene, or dibithienyl pentacene.

The optionally substituted polyene species may be any species that contains at least two pi-conjugated carbon-carbon double bonds. For example, the optionally substituted polyene species may contain a series of alternating carbon-carbon double bonds and carbon-carbon single bonds. In some embodiments, the optionally substituted polyene species may be an optionally substituted oligoene species. In some cases, the optionally substituted polyene species may be a diene, triene, tetraene, or another species containing a greater number of pi-conjugated carbon-carbon double bonds. In some cases, the polyene species may be substituted with one or more additional functional groups. It should be understood that an optionally substituted polyene containing any number of pi-conjugated carbon-carbon double bonds may be suitable for use in embodiments described herein. Those of ordinary skill in the art would be able to select a polyene species containing a desired number of pi-conjugated carbon-carbon double bonds and/or the appropriate number and types of functional groups on the polyene species in order to suit a particular application. In some embodiments, the optionally substituted polyene species is diphenylbutadiene, diphenylhexatriene, or diphenyloctatetraene. In some cases, the optionally substituted polyacene may include a heteroatom (e.g., oxygen, nitrogen, sulfur, phosphorus, etc.) For example, the optionally substituted polyacene may be diphenyl isobenzofuran, or the like.

In one set of embodiments, the donor material includes an organic compound that is not pentacene.

It should be understood that any of the donor materials described herein may be useful as exciton donor materials and/or electron donor materials.

Those of ordinary skill in the art will be able to select suitable acceptor materials (e.g., n-type materials) for use in the embodiments described herein, including materials that have more negative carriers (electrons) than positive carriers (holes). The acceptor material may also be any material capable of accepting electron and/or energy from a donor material. In some embodiments, the acceptor material includes an inorganic material, such as silicon, GaAs, perovskites, CdTe, or the like. In some embodiments, the acceptor material includes an organic material, such as fullerenes, nanotubes, and/or nanorods, any of which are optionally substituted. In one embodiment, the acceptor material is an optionally substituted fullerene. In one embodiment, the acceptor material is C₆₀. In some embodiments, the device may include more than one acceptor material. For example, the device may include a first, organic acceptor material (e.g., C₆₀) and a second, inorganic acceptor material (e.g., silicon).

It should be understood that any of the acceptor materials described herein may be useful as exciton acceptor materials and/or electron acceptor materials.

In some cases, the donor material is an organic material and the acceptor material is an inorganic material such that an organic-inorganic heterojunction is formed within the device. In some cases, the donor material is an optionally substituted polyacene or an optionally substituted polyene and the acceptor material is silicon.

The device may include additional components that may enhance device performance. For example, the device may include a component capable of facilitating energy transfer between the donor material and the acceptor material. In some cases, the donor material, alone, may not produce an emission under the operating conditions of the device, but when arranged in combination with another component, the donor material may produce an emission. In some embodiments, the donor material may be arranged in electronic or excitonic communication with a triplet emitter species such that an exciton may be transferred from the donor material to the triplet emitter species. The triplet emitter species may then produce an emission (e.g., phosphorescence). The triplet emitter species may also be arranged in optical or excitonic communication with the acceptor material such that an emission produced by the triplet emitter species may be absorbed by or transferred to the acceptor material. In some embodiments, the triplet emitter species may be arranged in physical contact with the donor material and/or the acceptor material. The triplet emitter species may be any species capable of interacting with a non-emissive triplet exciton to produce an emission, such as a phosphorescence. In some cases, the triplet emitter species may be an organic species. In some cases, the triplet emitter species comprises a metal species. For example, the triplet emitter species may be an organic macrocyclic species, optionally bound to a metal atom.

In some cases, the triplet emitter species is an optionally substituted porphine. In some cases, the triplet emitter species is porphine (or porphin), which is an aromatic heterocyclic macrocycle containing four unsubstituted pyrrole rings linked at their alpha-carbon atoms via methine bridges (═CH—). In some cases, the triplet emitter species is a substituted porphine, referred to as a porphyrins. The porphine and porphyrin species described herein may be bound to one or more metal atoms. Some specific examples of porphyrins include Pt(II) meso-tetraphenyl tetrabenzoporphine, Pt(II) tetraphenyl benzoporphine, Pt(II) octaethyl porphine, Pd(II) tetrabenzoporphine, Pt(II) meso-tetra(pentaflurophenyl) porphine, Pt(II) tetrabenzoporphine, Pd(II) meso-tetraphenyl porphine, Pt(II) aza-triphenyltetrabenzoporphyrin, and Pt (II) tetraphenyltetranaphtho[2,3]porphyrin.

In some embodiments, the triplet emitter species may be a nanoparticle, such as a semiconductor nanoparticle or quantum dot. In some cases, the triplet emitter species is a quantum dot containing one or more metals. Examples of quantum dots include Lead Sulfide (PbS), Lead Selenide (PbSe), Cadmium Sulfide (CdS), Cadmium Selenide (CdSe), Cadmium Telluride (CdTe), Indium Arsenide (InAs), Indium Phosphide (InP), Indium Antimonide (InSb), Zinc Sulfide (ZnS), Zinc Selenide (ZnSe), Zinc Telluride (ZnTe), Gallium Arsenide (GaAs), Gallium Phosphide (GaP), Gallium Antimonide (GaSb), Mercury Sulfide (HgS), Mercury Selenide (HgSe), Mercury Telluride (HgTe), Aluminum Arsenide (AlAs), Aluminum Phosphide (AlP), Aluminum Antimonide (AlSb). It should also be understood that other quantum dots, or alloys or mixtures of quantum dots, are also suitable for use in embodiments described herein. The specific composition of the quantum dot is typically selected, in part, to provide the desired optical properties within the device. For example, the quantum dot may be selected such that is capable of undergoing FRET with one or more components of the device, such as the donor material (e.g., singlet fission material) and the acceptor material (e.g., silicon material). In some embodiments, the quantum dot may be a lead-based composition such as PbS or PbSe. In some embodiments, the quantum dot may be a cadmium-based composition such as CdS or CdSe. In some embodiments, it may be preferred for the semiconductor nanoparticles to have a cadmium-based composition such as CdSe. In some embodiments, it may be preferred for the semiconductor nanoparticles to have an indium-based composition such as InAs. It is also possible for composites of the invention to quantum dots having different compositions.

The quantum dots generally have particle sizes of less than 100 nanometers. In some cases, the average particle size of the quantum dots in the composite is less than 20 nanometers; in other cases, the average particle size is less than 5 nanometers (e.g., about 3.5 nanometers). In some embodiments, the average particle size of the quantum dots is greater than 0.5 nanometers. Average particle size of a quantum dot may be determined, for example, using profilometry.

Any suitable conventional technique known in the art for forming quantum dots may be used. One suitable technique for quantum dots has been described in Peng et. al., J. Am. Chem Soc. 2001, 123, 183, which is incorporated herein by reference.

In some embodiments, the triplet emitter species is phosphorescent in the range of about 700 nm to about 1100 nm.

Those of ordinary skill in the art would be capable of selecting the appropriate combination of donor material, acceptor material, and, optionally, triplet emitter species, for use in devices described herein. In some cases, the donor material and/or acceptor material may be selected to enhance charge separation, which can increase the efficiency of the photovoltaic response to the material, for example, by preventing back electron transfer reactions and/or charge recombination. In some cases, the donor material is selected to have an emission that sufficiently overlaps with the absorption spectrum of the acceptor material, facilitating energy transfer from the donor material to the acceptor material.

In some cases, the device may also include a component that may aid in reducing energy loss via competitive processes. For example, the device may include an exciton blocking layer or an exciton confinement layer, which may reduce or prevent undesired quenching of excitons. In some cases, the exciton blocking layer may reduce exciton quenching at an exposed portion of the device, such as the surface of the device exposed to electromagnetic radiation (e.g., the “front” side).

In one set of embodiments, the exciton blocking layer includes a conducting polymer, or a mixture of polymers comprising at least one conducting polymer. Conducting polymers refer to extended molecular structures comprising a conjugated backbone (e.g., pi-conjugated backbone, sigma-conjugated backbone, etc.), where “backbone” refers to the longest continuous bond pathway of the polymer. Polymers may also include oligomers. Typically, conducting polymers include at least one portion along which electron density or electronic charge can be conducted, where the electronic charge is delocalized. For example, in pi-conjugated systems, p-orbitals of one monomer have sufficient overlap with p-orbitals of an adjacent monomer such that electronic charge may be delocalized. In some cases, a conjugated pi-backbone includes a plane of atoms directly participating in the conjugation, wherein the plane arises from a preferred arrangement of p-orbitals to maximize p-orbital overlap, thus maximizing conjugation and electronic conduction. Examples of conducting polymers include polyaniline, polythiophene, polypyrrole, polyphenylene, polyarylene, poly(bisthiophene phenylene), a ladder polymer, poly(arylene vinylene), poly(arylene ethynylene), metal derivatives thereof, or substituted derivatives thereof. In some embodiments, the conducting polymer may be polythiophene or a substituted derivative thereof. In an illustrative embodiment, the conducting polymer is poly(3-hexylthiophene). In another illustrative embodiment, the conducting polymer is a mixture of poly(3,4-ethylenedioxythiophene) and poly(styrenesulfonate) (PEDOT:PSS).

In some embodiments, poly(3-hexylthiophene) may be useful as an exciton blocking layer for pentacene, which has a relatively high energy HOMO (highest occupied molecular orbital). Combination of these materials within the device may result in an increase in the peak external quantum efficiency. In an illustrative embodiment, a device was fabricated to include a layer of poly(3-hexylthiophene) formed on a 15 nm thick film of pentacene, and the materials were placed in contact with two electrodes. External quantum efficiencies of 80% or greater (e.g., 82%) were achieved with the device, and the quantum efficiency was increased to 109%.

The components of the device may arranged in various configurations. In some cases, the donor material, the acceptor material, and, optionally, a triplet emitter species, may be formed as layers or films. In some embodiments, the acceptor material and/or the triplet emitter species may be dispersed in clusters throughout the donor material. In some embodiments, the donor material and/or the triplet emitter species may be dispersed in clusters throughout the acceptor material. In some cases, the components may be randomly dispersed with respect to one another, thereby forming a heterogeneous material. In some cases, an array of different devices with different compositions and different morphologies or different layouts can be used. In some embodiments, the device may include a layer containing a mixture of the donor material and the triplet emitter species, as shown in FIGS. 2B-2C.

In some cases, the device may be configured as a back-contacted device, i.e., may have electrical contacts (e.g., cathode, anode) primarily in contact with one side or “back” of the device. For example, a back-contacted device may include an donor material, an acceptor material having a first side in physical contact with the donor material, and at least one electrical contact in physical contact with the second, opposing side of the acceptor material such that the donor material is substantially not in physical contact with the at least one electrical contact. In this configuration, the “front” side of the device may be available for treatment, modification, or for the addition of other device components. For example, the “front” side of the device may be open for passivation, anti-reflection coatings, and the like.

In some embodiments, a second device may be arranged on the “front” side of the device, to form a system of tandem devices. FIG. 2C shows an illustrative embodiment of a system where a first solar cell (e.g., inorganic material) may be configured to have both an n+ contact and a p+ contact arranged on the “back” side of the first solar cell. A second solar cell (e.g., organic material such as a singlet fission material) may then be built on the “front” side of the first solar cell, with a top contact (e.g., organic front contact), resulting in a three terminal device. An external circuit may then be arranged such that the system functions as two parallel tandem cells, facilitating spectrum splitting. For example, the first solar cell may be a silicon solar cell and the second solar cell may comprise a singlet fission material. For systems where a second solar cell featuring a singlet fission material or a high open circuit voltage is arranged on the “front” of a back-contacted silicon solar cell, efficiency may be increased when the product of the open circuit voltage and the internal quantum efficiency are greater than that of silicon.

In some embodiments, components of devices described herein may be provided in the form of films or layers, such as a thin films. For example, one or more of the donor material, acceptor material, triplet emitter species, exciton blocking layer, electrodes or electrical contacts, or other components, may be provided in the form of thin films or layers such that a multilayer stack is formed. In some cases, the thickness of the film may be between about 1 nm and about 1 μm, or between about 1 nm and about 500 nm, or between about 1 nm and about 500 nm, or between about 1 nm and about 250 nm, or between about 1 nm and about 100 nm. Film thicknesses may be measured using profilometry.

In some embodiments, it may be desirable to provide the donor material as a relatively thin film. In some cases, the thickness of the donor material may be from about 1 nm to about 250 nm, from about 1 nm to about 50 nm, or from about 1 nm to about 25 nm (e.g., 15 nm). It should be understood that in some embodiments, a relatively greater thickness may be desired (e.g., greater than 100 nm).

Those of ordinary skill in the art will be aware of methods for forming films or layers of various components, including solution coating, ink jet printing, spin coating, dip coating, spray coating, evaporation techniques such as chemical vapor deposition and the like. In some embodiments, a solution may be provided comprising the donor material, the acceptor material, and/or an optional triplet emitter species in a solvent (e.g., tetrahydrofuran, toluene, benzene, diethyl ether, hexanes, dimethylsulfoxide, etc.). One or more, or all of the components to be incorporated in the film may be soluble or substantially soluble in the solvent. The solution may be placed on, or in contact with, a substrate or other component of the device, and the solvent may be evaporated, thereby forming a film. In some cases, a mixture of the donor material, the acceptor material, and/or an optional triplet emitter species may be directly evaporated onto a surface (e.g., in the absence of a solvent).

Devices described herein may be exposed to electromagnetic radiation using methods known to those of ordinary skill in the art. In some embodiments, electromagnetic radiation is applied to the device to produce an excitation energy (e.g., a photonic energy) which can then be converted to electricity. In some cases, the conversion occurs electrically. In some embodiments, the conversion occurs optically (e.g., via FRET).

In an illustrative embodiment, the device may include pentacene as an exciton donor material, a fullerene (e.g., C₆₀) as an exciton acceptor material, poly(3-hexylthiophene) as an exciton blocking layer, indium tin oxide (ITO) and poly(3,4-ethylenedioxythiophene) poly(styrenesulfonate) (PEDOT:PSS) as the anode, and silver bathocuproine (BCP) and a silver cap as the cathode.

In another illustrative embodiment, the device may include pentacene as an exciton donor material, silicon as an exciton acceptor material, poly(3-hexylthiophene) as an exciton blocking layer, indium tin oxide (ITO) and poly(3,4-ethylenedioxythiophene) poly(styrenesulfonate) (PEDOT:PSS) as the anode, and silver bathocuproine (BCP) and a silver cap as the cathode (or simply silver as the cathode).

In another illustrative embodiment, the device may include tetracene or a substituted tetracene as an exciton donor material, silicon as an exciton acceptor material, poly(3-hexylthiophene) as an exciton blocking layer, indium tin oxide (ITO) and poly(3,4-ethylenedioxythiophene) poly(styrenesulfonate) (PEDOT:PSS) as the anode, and silver bathocuproine (BCP) and a silver cap as the cathode (or simply silver as the cathode).

Devices described herein may exhibit solar conversion efficiencies that exceed the maximum theoretical efficiency of a solar cell using a p-n junction to collect power from the cell (i.e., may exceed the Shockley-Queisser efficiency limit of 34%). In some cases, a single device may exhibit a solar conversion efficiency greater than 34%. In some cases, a single device may exhibit a solar conversion efficiency in the range of about 34% to about 100%. For example, a single device may exhibit a solar conversion efficiency of about 30%, about 35%, about 40%, or about 45%, for a single device.

Devices described herein may exhibit increased internal quantum efficiency (IQE), which is defined as the number of electrons collected per photon absorbed. In some cases, the device may exhibit an internal quantum efficiency of about 50%, about 60%, about 70%, about 80%, about 90%, about 100%, about 110%, about 120%, about 130%, about 140%, about 150%, about 160%, about 170%, about 180%, about 190%, or about 200%.

In some cases, the devices described herein may exhibit increased external quantum efficiency, defined as the ratio between the number of electrons flowing out of the device and the number of photons incident upon the device. In some cases, the device may exhibit an external quantum efficiency of about 20%, about 25%, about 30%, about 35%, about 40%, about 45%, about 50%, about 55%, about 60%, about 65%, about 70%, about 75%, about 80%, about 85%, about 90%, about 95%, about 100%, about 105%, about 110%, about 115%, about 120%, about 125%, about 130%, about 135%, about 140%, about 145%, about 150%, about 155%, about 160%, about 165%, about 170%, about 175%, about 180%, about 185%, about 190%, about 195%, or about 200%, in the visible region.

Devices described herein may also exhibit increased power conversion. In some cases, the device may exhibit power conversion of about 10%, about 15%, about 20%, about 25%, about 30%, about 35%, about 40%, or about 45%.

Methods for producing a photocurrent are also provided. For example, the method may involve exposure of a device described herein to a source of energy (e.g., electromagnetic energy) to produce an excitation energy. The excitation energy may then be transferred between various components of the device as described herein to produce a photocurrent. In one set of embodiments, the excitation energy may be transferred from a singlet fission material to the acceptor material (e.g., via the triplet emitter species) such that the device produces a photocurrent.

As used herein, the term “fullerene” is given its ordinary meaning in the art and refers to a substantially spherical molecule generally comprising a fused network of five-membered and/or six-membered aromatic rings. For example, C₆₀ is a fullerene which mimics the shape of a soccer ball. The term fullerene may also include molecules having a shape that is related to a spherical shape, such as an ellipsoid. It should be understood that the fullerene may comprise rings other than six-membered rings. In some embodiments, the fullerene may comprise seven-membered rings, or larger. Fullerenes may include C₃₆, C₅₀, C₆₀, C₆₁, C₇₀, C₇₆, C₈₄, and the like. Fullerenes may also comprise individual atoms, ions, and/or nanoparticles in the inner cavity of the fullerene. A non-limiting example of a substituted fullerene which may be used as the n-type material is phenyl-C₆₁-butyric acid methyl ester.

Those of ordinary skill in the art would be able to select materials suitable for use as electrodes in the context of embodiments described herein. In some cases, the electrode material may comprise calcium, aluminum, silver, lithium fluoride, or the like. In some embodiments, the electrode material comprises silver. The electrode may also include additional components, such as various coatings (e.g., polymer coatings) and caps (e.g., metal caps) known in the art. In some embodiments, indium tin oxide (ITO) and poly(3,4-ethylenedioxythiophene) poly(styrenesulfonate) (PEDOT:PSS) may be used as an anode, In some cases, silver, or bathocuproine (BCP) and a silver cap, may be used as the cathode.

The substrate can be any material capable of supporting the device components described herein. That is, the substrate may be any material to which the photoactive material, electrode material, or other compositions described herein, may adhere. The substrate may be selected to have a thermal coefficient of expansion similar to those of the other components of the device to promote adhesion and prevent separation of the device components at various temperatures. In some instances, materials with dissimilar thermal expansion coefficients may expand and contract at different rates and amounts with changes in temperature, which can cause stress and separation of the device components.

In some cases, the substrate may also function as an electrode within the devices. In some cases, the substrate may comprise an electrically conductive material. In some cases, the substrate may comprise a material coated with an electrically conductive material, such that the photoactive material may be formed in contract with the electrically conductive material. Examples of materials suitable for use as a substrate include, but are not limited to, metals, such as nickel, chromium, gold, molybdenum, tungsten, platinum, titanium, aluminum, copper, palladium, silver, other metals and/or metal compounds, alloys thereof, intermetallic compounds thereof, and the like. Other materials may also be useful, including indium tin oxide (ITO).

The substrate may also comprise a flexible material, such as plastics (e.g., polymer), polymer films, flexible glass films, metal foil, paper, woven materials, combinations thereof, and the like. The substrate may be a flexible material coated with an electrically conductive material, for example. The substrate may be prepared, for example, by one of a number of micromachining methods known to those skilled in the art. Examples of such methods include, for instance, photofabrication, etching, electrodischarge machining, electrochemical machining, laser beam machining, wire electrical discharge grinding, focused ion beam machining, micromilling, micro-ultrasonic machining, and micropunching. The dimensions of the substrate may be any length, width, and thickness that is desired for a particular end use and may be rectangular, circular or otherwise shaped.

Various components of a device, such as the electrodes, power source, electrolyte, separator, container, circuitry, insulating material, gate electrode, etc. can be fabricated and/or selected by those of ordinary skill in the art from any of a variety of components, as well as those described in any of those patent applications described herein. Components may be molded, machined, extruded, pressed, isopressed, infiltrated, coated, in green or fired states, or formed by any other suitable technique. Those of ordinary skill in the art are readily aware of techniques for forming components of devices herein. Electromagnetic radiation may be provided to the systems, devices, electrodes, and/or for the methods described herein using any suitable source.

As used herein, the term “substituted” is contemplated to include all permissible substituents of organic compounds, “permissible” being in the context of the chemical rules of valence known to those of ordinary skill in the art. It will be understood that “substituted” also includes that the substitution results in a stable compound, e.g., which does not spontaneously undergo transformation such as by rearrangement, cyclization, elimination, etc. In some cases, “substituted” may generally refer to replacement of a hydrogen with a substituent as described herein. However, “substituted,” as used herein, does not encompass replacement and/or alteration of a key functional group by which a molecule is identified, e.g., such that the “substituted” functional group becomes, through substitution, a different functional group. For example, a “substituted phenyl group” must still comprise the phenyl moiety and cannot be modified by substitution, in this definition, to become, e.g., a pyridine ring. In a broad aspect, the permissible substituents include acyclic and cyclic, branched and unbranched, carbocyclic and heterocyclic, aromatic and nonaromatic substituents of organic compounds. Illustrative substituents include, for example, those described herein. The permissible substituents can be one or more and the same or different for appropriate organic compounds. For purposes of this invention, the heteroatoms such as nitrogen may have hydrogen substituents and/or any permissible substituents of organic compounds described herein which satisfy the valencies of the heteroatoms.

Examples of substituents include, but are not limited to, aliphatic, alicyclic, heteroaliphatic, heteroalicyclic, halogen, azide, alkyl, aralkyl, alkenyl, alkynyl, cycloalkyl, hydroxyl, alkoxyl, amino, nitro, sulfhydryl, imino, amido, phosphonate, phosphinate, carbonyl, carboxyl, silyl, ether, alkylthio, heteroalkylthio, heteroarylthio, sulfonyl, sulfonamido, ketone, aldehyde, ester, heterocyclyl, aromatic or heteroaromatic moieties, —CF₃, —CN, aryl, aryloxy, perhaloalkoxy, aralkoxy, heteroaryl, heteroaryloxy, heteroarylalkyl, heteroaralkoxy, azido, amino, halide, alkylthio, oxo, acylalkyl, carboxy esters, -carboxamido, acyloxy, aminoalkyl, alkylaminoaryl, alkylaryl, alkylaminoalkyl, alkoxyaryl, arylamino, aralkylamino, alkylsulfonyl, -carboxamidoalkylaryl, -carboxamidoaryl, hydroxyalkyl, haloalkyl, alkylaminoalkylcarboxy-, aminocarboxamidoalkyl-, cyano, alkoxyalkyl, perhaloalkyl, arylalkyloxyalkyl, (e.g., SO₄(R′)₂), a phosphate (e.g., PO₄(R′)₃), a silane (e.g., Si(R′)₄), a urethane (e.g., R′O(CO)NHR′), and the like. Additionally, the substituents may be selected from F, Cl, Br, I, —OH, —NO₂, —CN, —NCO, —CF₃, —CH₂CF₃, —CHCl₂, —CH₂OR—, —CH₂CH₂OR—, —CH₂N(Rₓ)₂, —CH₂SO₂CH₃, —C(O)R—, —CO₂(Rₓ), —CON(Rₓ)₂, —OC(O)R—, —C(O)OC(O)Rₓ, —OCO₂R—, —OCON(Rₓ)₂, —N(Rₓ)₂, —S(O)₂R—, —OCO₂R—, —NRₓ(CO)Rₓ, —NRₓ(CO)N(Rₓ)₂, wherein each occurrence of Rₓ independently includes, but is not limited to, H, aliphatic, alicyclic, heteroaliphatic, heteroalicyclic, aryl, heteroaryl, alkylaryl, or alkylheteroaryl, wherein any of the aliphatic, alicyclic, heteroaliphatic, heteroalicyclic, alkylaryl, or alkylheteroaryl substituents described above and herein may be substituted or unsubstituted, branched or unbranched, cyclic or acyclic, and wherein any of the aryl or heteroaryl substituents described above and herein may be substituted or unsubstituted.

In general, the term “aliphatic,” as used herein, includes both saturated and unsaturated, straight chain (i.e., unbranched) or branched aliphatic hydrocarbons, which are optionally substituted with one or more functional groups, as defined below. As will be appreciated by one of ordinary skill in the art, “aliphatic” is intended herein to include, but is not limited to, alkyl, alkenyl, alkynyl moieties. Illustrative aliphatic groups thus include, but are not limited to, for example, methyl, ethyl, n-propyl, isopropyl, allyl, n-butyl, sec-butyl, isobutyl, tert-butyl, n-pentyl, sec-pentyl, isopentyl, tert-pentyl, n-hexyl, sec-hexyl, moieties and the like, which again, may bear one or more substituents, as previously defined.

As used herein, the term “alkyl” is given its ordinary meaning in the art and may include saturated aliphatic groups, including straight-chain alkyl groups, branched-chain alkyl groups, cycloalkyl (alicyclic) groups, alkyl substituted cycloalkyl groups, and cycloalkyl substituted alkyl groups. An analogous convention applies to other generic terms such as “alkenyl,” “alkynyl,” and the like. Furthermore, as used herein, the terms “alkyl,” “alkenyl,” “alkynyl,” and the like encompass both substituted and unsubstituted groups.

In some embodiments, a straight chain or branched chain alkyl may have 30 or fewer carbon atoms in its backbone, and, in some cases, 20 or fewer. In some embodiments, a straight chain or branched chain alkyl has 12 or fewer carbon atoms in its backbone (e.g., C₁-C₁₂ for straight chain, C₃-C₁₂ for branched chain), has 6 or fewer, or has 4 or fewer. Likewise, cycloalkyls have from 3-10 carbon atoms in their ring structure or from 5, 6 or 7 carbons in the ring structure. Examples of alkyl groups include, but are not limited to, methyl, ethyl, propyl, isopropyl, cyclopropyl, butyl, isobutyl, tert-butyl, cyclobutyl, hexyl, cyclochexyl, and the like. In some cases, the alkyl group might not be cyclic. Examples of non-cyclic alkyl include, but are not limited to, methyl, ethyl, propyl, isopropyl, n-butyl, tert-butyl, n-pentyl, neopentyl, n-hexyl, n-heptyl, n-octyl, n-decyl, n-undecyl, and dodecyl.

The terms “alkenyl” and “alkynyl” refer to unsaturated aliphatic groups analogous in length and possible substitution to the alkyls described above, but that contain at least one double or triple bond respectively. Alkenyl groups include, but are not limited to, for example, ethenyl, propenyl, butenyl, l-methyl-2-buten-1-yl, and the like. Non-limiting examples of alkynyl groups include ethynyl, 2-propynyl (propargyl), 1-propynyl, and the like.

The terms “heteroalkenyl” and “heteroalkynyl” refer to unsaturated aliphatic groups analogous in length and possible substitution to the heteroalkyls described above, but that contain at least one double or triple bond respectively.

As used herein, the term “halogen” or “halide” designates —F, —Cl, —Br, or —I.

The term “aryl” refers to aromatic carbocyclic groups, optionally substituted, having a single ring (e.g., phenyl), multiple rings (e.g., biphenyl), or multiple fused rings in which at least one is aromatic (e.g., 1,2,3,4-tetrahydronaphthyl, naphthyl, anthryl, or phenanthryl). That is, at least one ring may have a conjugated Pi electron system, while other, adjoining rings can be cycloalkyls, cycloalkenyls, cycloalkynyls, aryls, and/or heterocycyls. The aryl group may be optionally substituted, as described herein. “Carbocyclic aryl groups” refer to aryl groups wherein the ring atoms on the aromatic ring are carbon atoms. Carbocyclic aryl groups include monocyclic carbocyclic aryl groups and polycyclic or fused compounds (e.g., two or more adjacent ring atoms are common to two adjoining rings) such as naphthyl group. Non-limiting examples of aryl groups include phenyl, naphthyl, tetrahydronaphthyl, indanyl, indenyl and the like.

The terms “heteroaryl” refers to aryl groups comprising at least one heteroatom as a ring atom, such as a heterocycle. Non-limiting examples of heteroaryl groups include pyridyl, pyrazinyl, pyrimidinyl, pyrrolyl, pyrazolyl, imidazolyl, thiazolyl, oxazolyl, isooxazolyl, thiadiazolyl, oxadiazolyl, thiophenyl, furanyl, quinolinyl, isoquinolinyl, and the like.

It will also be appreciated that aryl and heteroaryl moieties, as defined herein, may be attached via an aliphatic, alicyclic, heteroaliphatic, heteroalicyclic, alkyl or heteroalkyl moiety and thus also include -(aliphatic)aryl, -(heteroaliphatic)aryl, -(aliphatic)heteroaryl, -(heteroaliphatic)heteroaryl, -(alkyl)aryl, -(heteroalkyl)aryl, -(heteroalkyl)aryl, and -(heteroalkyl)-heteroaryl moieties. Thus, as used herein, the phrases “aryl or heteroaryl” and “aryl, heteroaryl, (aliphatic)aryl, -(heteroaliphatic)aryl, -(aliphatic)heteroaryl, -(heteroaliphatic)heteroaryl, -(alkyl)aryl, -(heteroalkyl)aryl, -(heteroalkyl)aryl, and -(heteroalkyl)heteroaryl” are interchangeable. The term “arylalkyl,” as used herein, refers to a group comprising an aryl group attached to the parent molecular moiety through an alkyl group.

The term “arylheteroalkyl,” as used herein, refers to a group comprising an aryl group attached to the parent molecular moiety through a heteroalkyl group.

The term “heteroarylalkyl,” as used herein, refers to a group comprising a heteroaryl group attached to the parent molecular moiety through an alkyl group.

Having thus described several aspects of some embodiments of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

### EXAMPLES

### Example 1

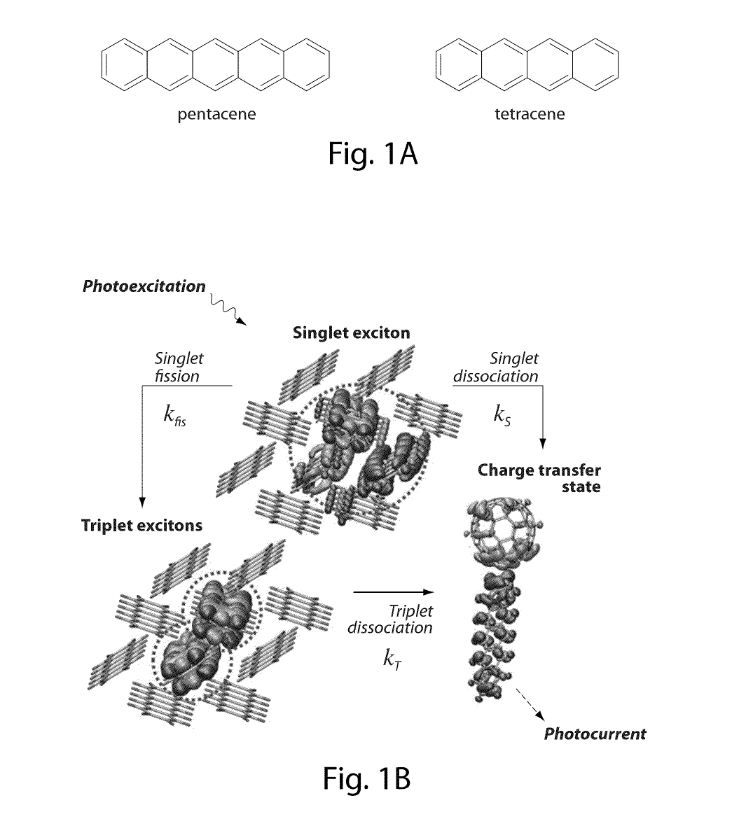

In the following example, a device containing a pentacene/C₆₀ donor-acceptor junction is investigated. To overcome the Shockley-Queisser limit, solar cells can combine fission with a conventional material that fills in the absorption spectrum above the dark exciton. In this example, it is demonstrated how singlet-fission can break the conventional barrier of one electron per photon. An example of a fission material is pentacene, a polyacene species with five, fused benzene rings, as shown in FIG. 1A. FIG. 1B shows a schematic of singlet exciton fission in pentacene based on calculations of the singlet and triplet excitons and charge transfer states at the pentacene/fullerene interface. FIG. 1B indicates where electron density can be found in the excited state, and the delocalized singlet exciton and two localized triplet excitons are indicated by dotted circles. The loss pathway for singlet excitons is direct dissociation into charge prior to singlet exciton fission.

In pentacene, optical excitation generates a delocalized spin 0, or singlet, exciton. Within about 80 fs, the pentacene singlet exciton splits into a pair of spin 1, or triplet, excitons. A pair of triplet excitons can be combined in nine different spin states. As some triplet-pair states have singlet character (total spin of 0), singlet fission is spin-allowed. Under an applied magnetic field, the singlet character of the triplet-pair states can be redistributed, changing the number of states with singlet character. Thus, the rate of singlet fission is typically dependent on the local magnetic field, offering a unique probe of fission dynamics in thin films and devices. Although triplet excitons are dark states, energy may be extracted from them if they are dissociated into charge. Such a process may occur at a junction between an organic donor material like pentacene and an acceptor material such as fullerene C₆₀, for example, when pentacene is oriented approximately perpendicular to the interface.

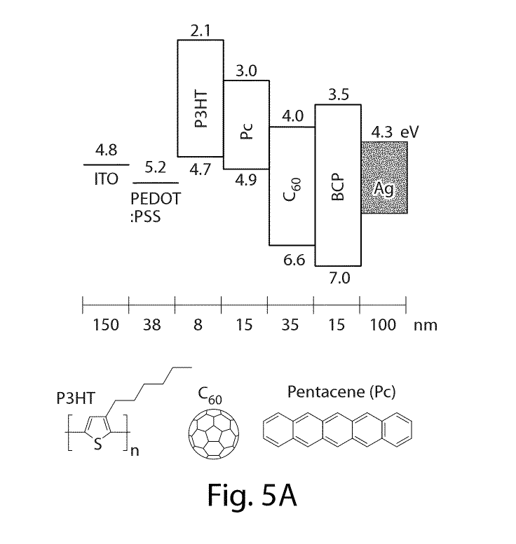

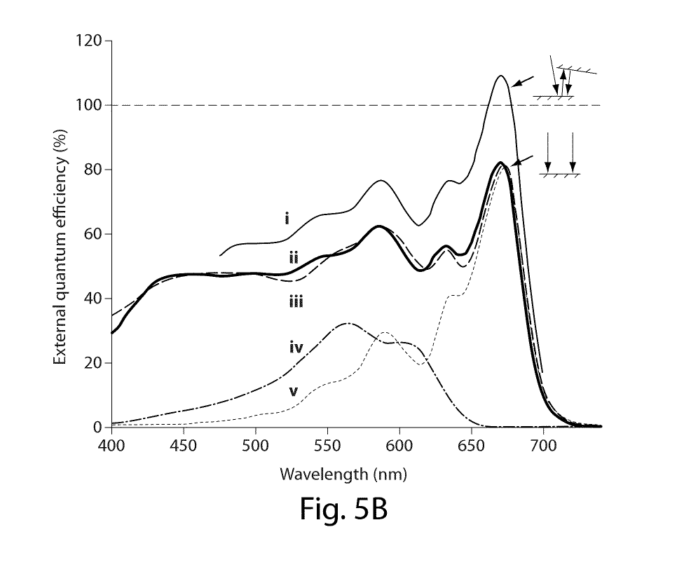

To demonstrate, a pentacene-based solar cell containing a pentacene/C₆₀ donor-acceptor junction was fabricated as shown in FIG. 5A. FIG. 5A shows the chemical structures and architecture of the solar cell with the thickness of each layer shown in nanometers and energy levels of the lowest unoccupied and highest occupied molecular orbitals shown in eV. The anode was composed of indium tin oxide (ITO) and poly(3,4-ethylenedioxythiophene) poly(styrenesulfonate) (PEDOT:PSS). The cathode employed bathocuproine (BCP) and a silver cap. The device included a thin pentacene layer (15 nm thickness) as an donor material and C₆₀ as an acceptor material, as well as an exciton blocking layer of regio-regular poly(3-hexylthiophene) (P3HT) placed between the pentacene and the anode to minimize triplet exciton losses. The combination of the wide energy gap and 1.5 eV triplet energy of P3HT confined pentacene triplet excitons, and its highest occupied molecular orbital (HOMO) of 4.7 eV helped extract holes from pentacene. To maximize light absorption, devices were fabricated with MgF₂ antireflection coatings on the front surface of the glass substrate.

FIG. 5B shows the external quantum efficiency (EQE) FIG. 5 for the device in FIG. 5A. The EQE at normal incidence was (82±1)% at the peak pentacene absorption wavelength λ=670 nm. Optical modeling predicted that the internal quantum efficiency (IQE) for photoexcitation of pentacene and P3HT is (160±10)% and (150±10)%, respectively. The IQE of pentacene in this solar cell was approximately double that reported previously for pentacene, and the high IQE of P3HT was consistent with the expected sensitization of P3HT by pentacene, as singlet excitons generated in P3HT were transferred to pentacene and then split into triplets. The peak EQE dropped to 24% when P3HT is absent. The P3HT appeared to block triplet diffusion to the anode and suppress recombination by improving hole extraction.

The 15-nm-thick film of pentacene in the solar cell microcavity absorbed only 49% of the incident light at λ=670 nm according to optical modeling, indicating that efficiency may further improve if a light-trapping scheme is employed. Therefore, the EQE was measured in configurations designed to simulate two conventional optical trapping schemes. The first scheme involved mounting the cell at 45° to the incident light, with a mirror that directed reflected photons back to the device. This configuration models a saw tooth geometry such that incident light bounces at least twice within the structure. In the second scheme, the incident angle was reduced to 10° from the normal, modeling an optical collector that focused light through a small hole in a mirror held parallel to the surface of the cell. The peak EQE at λ=670 nm for the solar cell mounted at 45° was (102±1)%, increasing to (109±1)% for incidence at 10° from the normal. Both light-trapping schemes yielded efficiencies that met or exceeded the one electron per incident photon benchmark.

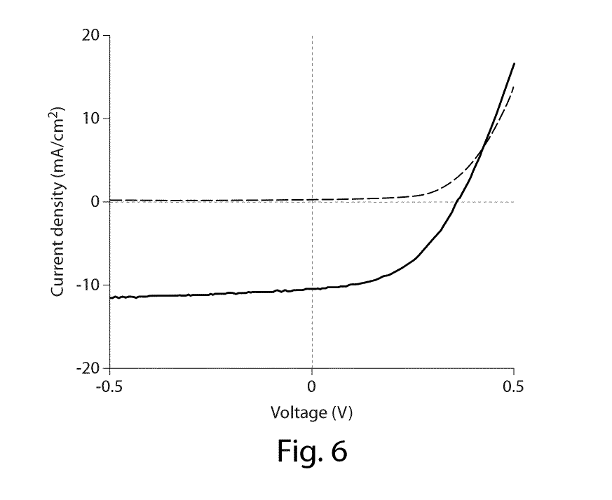

As shown in FIG. 6, the current density-voltage characteristic of the pentacene solar cell measured under dark (dotted line) or AM1.5G 100 mW/cm2 (solid line) conditions without optical trapping. The short circuit current measured at AM1.5 matched the integrated EQE measured at <1 mW/cm² to within 6%, demonstrating that the fission process in pentacene was not significantly intensity dependent. As expected, the enhanced EQE did not correspond to a high power efficiency. The open circuit voltage was 0.36 V, identical to the values of previous pentacene devices. It is defined by the pentacene triplet energy of 0.86 eV. With C₆₀ as the acceptor, the device absorbed light only above the pentacene singlet energy at 1.8 eV. Consequently, the power efficiency was (1.8±0.1)%.

Independent confirmation of the high internal quantum efficiency within the cell was provided by analysis of the photocurrent under a magnetic field. The crucial rates are identified in FIG. 1. The singlet exciton can either directly dissociate into a single electron-hole pair, k_{S}, or undergo fission resulting in generation of two electron-hole pairs, k_{fis}(B). In absence of a magnetic field, three out of nine triplet-pair states have singlet character. Under a high magnetic field (B>0.2 T), the number of triplet-triplet pairs with singlet character reduces to two, reducing the singlet fission rate, k_{fis}(B). The photocurrent yield changed if there was effective competition between fission and the dissociation of the singlet exciton. Note that it is difficult to generate a magnetic field effect on the photocurrent yield unless there is a singlet loss mechanism that competes with the fission process.

For convenience, k_{fis}(B)=χ(B)k_{fis}⁰, where χ(B) is the modulation of the zero-field fission rate k_{fix}⁰. The normalized change in photocurrent in steady state, 6, is then given by Eq. 1:

$$δ = \frac{I ( B ) - I ( 0 )}{I ( 0 )} = \frac{{k}_{s} {k}_{fis}^{0} ( χ - 1 )}{( 2 {k}_{fis}^{0} + {k}_{s} ) ( χ {k}_{fis}^{0} + {k}_{s} )} , \qquad ( 1 )$$

where I(B) is the photocurrent as a function of magnetic field strength. Dissociation of the singlet exciton directly into charge may compete with fission for pentacene molecules directly adjacent to the acceptor. Indeed, reductions in the singlet exciton lifetime of pentacene have been observed in very thin pentacene films (0.6 monolayer) adjacent to a C₆₀ layer. Thus, pentacene films of varying thickness can be modeled by changing the effective rate of singlet dissociation in Eq. 1. Analytically, at a given value of the magnetic field, χ can be determined by noting that the magnitude of δ is maximized when kₛ=k_{fis}⁰\sqrt{2χ}. This yields Eq. 2:

$$χ = \frac{2 {δ}_{max}^{2} + {δ}_{max} + 1 + 2 \sqrt{2} {δ}_{max} \sqrt{{δ}_{max} + 1}}{{( {δ}_{max} - 1 )}^{2}} . \qquad ( 2 )$$

The result for χ can be used to directly obtain the triplet yield of singlet fission from the magnetic field modulation in photocurrent (Eq. 3):

$${η}_{fis} = \frac{2}{1 + {k}_{s} / {k}_{fis}^{0}} = \frac{( 1 - δ ) χ - 1 \pm \sqrt{{( δ ( χ + 2 ) - χ + 1 )}^{2} - 8 {δ}^{2} χ}}{( δ + 1 ) ( χ - 1 )} . \qquad ( 3 )$$

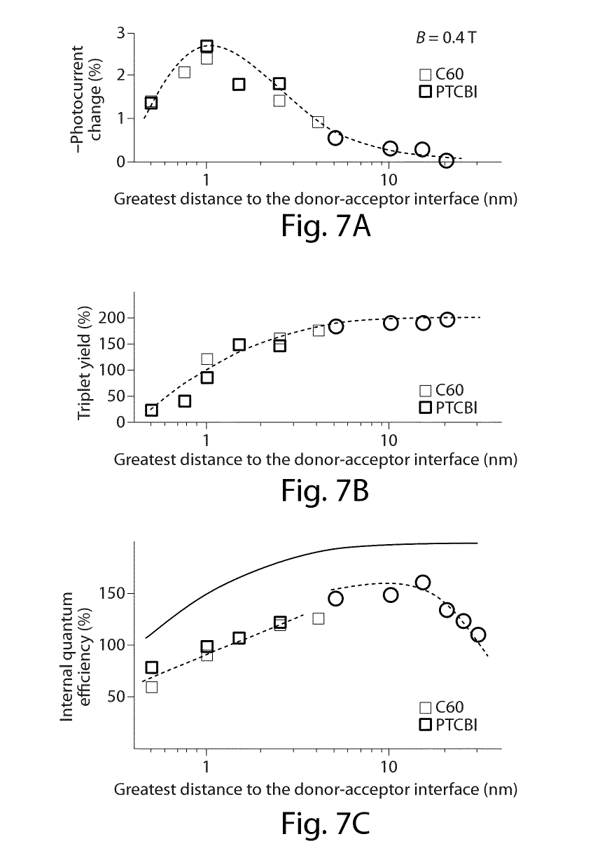

To obtain an independent measure of the yield of singlet fission, multiple devices were fabricated while varying the thickness of pentacene, as plotted in FIG. 7. FIG. 7A shows the magnetic field dependent change in photocurrent measured at B=0.4 T as a function of pentacene layer thickness. The square symbols are measured in photodetector structures and each pentacene layer is sandwiched between either C₆₀ or PTCBI acceptor films. Measurements in the solar cell architecture of FIG. 5A are circles (o). FIG. 7B shows the triplet yield from singlet exciton fission as obtained from Eq. 3. FIG. 7C shows a comparison of the maximum achievable quantum yield determined from the magnetic field effect (—) with the internal quantum efficiency as determined from EQE measurements and the calculated optical absorption. The reduction in quantum efficiency observed in thin layers of pentacene was found to originate in incomplete singlet exciton fission. Dashed lines are included simply as a visual guide.

For thin layers of pentacene (d<5 nm) optical absorption was increased by employing the multilayer photodetector architecture. Photodetectors were measured in reverse bias to improve charge extraction. As a test of generality, both C₆₀ and 3,4,9,10-perylene tetracarboxylic bisbenzimidazole (PTCBI) were used as acceptor molecules and found to yield similar results. Devices with thicker layers of pentacene employed the same device architecture as in FIG. 5A. The magnetic field modulation of photocurrent at 0.4 T is shown in FIG. 7A. It peaks at δₘₐₓ=−(2.7±0.1)% in 2-nm-thick layers of pentacene sandwiched between acceptor layers. From Equation 2, x=0.85, identical to the value obtained previously by measurements of tetracene.

In FIG. 7B, Equation 3 is utilized to transform the magnetic field modulation data into the expected yield of triplet excitons from singlet fission. Singlet fission is found to be incomplete in pentacene films with thickness d<5 nm, accounting for the relatively low IQE in the photodetector structures. The triplet yield approaches 200% in thicker films, providing independent confirmation of the high IQE calculated for the device structure shown in FIG. 5.

The IQE, as evaluated using optical modeling, is shown in FIG. 7C and compared to predictions based on the magnetic field effect. The IQE is suppressed in thin layers of pentacene, increases to a maximum for d˜15 nm, and then is reduced in thicker films. Decreases in IQE for thicker films are presumably due to triplet exciton diffusion limitations and lower than unity charge collection efficiency. There are two important conclusions from this IQE comparison. First, the yield of singlet fission can be conveniently determined directly from the normalized change in photocurrent under a magnetic field. A high yield is characterized by a vanishing modulation of photocurrent under magnetic field. Second, singlet fission in pentacene requires a relatively thick film to minimize losses due to singlet exciton dissociation. Fission is not effective in fine-grained blends of pentacene and fullerene or perylene-based acceptors.

In conclusion, the observation of external quantum yields exceeding 100% in the visible spectrum represents a significant advance in the application of singlet fission to solar cells.

What is claimed:

1. A device, comprising:
a donor material comprising an optionally substituted polyacene species or an optionally substituted polyene species;
an acceptor material having a first side in physical contact with the donor material, and a second, opposing side; and
at least one electrical contact in physical contact with the second, opposing side of the acceptor material,
wherein the donor material is not in physical contact with an electrical contact.

2-24. (canceled)

25. A device, comprising:
a donor material comprising an organic compound having a singlet energy and a triplet energy, wherein the singlet energy is about two times greater than the triplet energy;
an acceptor material having a first side in physical contact with the donor material, and a second, opposing side; and
at least one electrical contact in physical contact with the second, opposing side of the acceptor material,
wherein the donor material is not in physical contact with an electrical contact.

26-50. (canceled)

51. A device, comprising:
a donor material comprising an organic compound;
an acceptor material having a first side in physical contact with the donor material, and a second, opposing side; and
at least one electrical contact in physical contact with the second, opposing side of the acceptor material,
wherein the organic compound is not pentacene.

52-75. (canceled)

76. A device, comprising:
a singlet fission material comprising an organic compound having a singlet energy and a triplet energy, wherein the singlet energy is about two times greater than the triplet energy;
a triplet emitter species in electronic or excitonic communication with the singlet fission material; and
a silicon material in optical or excitonic communication with the triplet emitter species.

77-93. (canceled)

94. A method for producing a photocurrent, comprising:
exposing a device comprising a singlet fission material comprising an organic compound in electronic or excitonic communication with a triplet emitter species, and an acceptor material in optical or excitonic communication with the triplet emitter, to a source of energy to produce an excitation energy within the singlet fission material; and
allowing the excitation energy to transfer from the singlet fission material to the acceptor material (e.g., via the triplet emitter species) such that the device produces a photocurrent.

95-116. (canceled)

117. A device, comprising:
a singlet fission material;
an organic electron acceptor material or an organic electron donor material in contact with the singlet fission material; and
an inorganic material in physical contact with the singlet fission material.

118-137. (canceled)
